(19) United States
(12) Patent Application Publication
(10) Pub. No.: US 2021/0216688 A1
(43) Pub. Date: Jul. 15, 2021

(54) CONFIGURING AERODYNAMIC SIMULATION OF A VIRTUAL OBJECT

(71) Applicant: Microsoft Technology Licensing, LLC, Redmond, WA (US)

(72) Inventor: Sebastian WLOCH, Villenave d'Ornon (FR)

(73) Assignee: Microsoft Technology Licensing, LLC, Redmond, WA (US)

(21) Appl. No.: 16/741,414

(22) Filed: Jan. 13, 2020

(51) Int. Cl. G06F 30/28; G06F 30/15

(52) U.S. Cl. CPC G06F 30/28; G06F 30/15

(57) ABSTRACT

The specification is directed to aerodynamic simulation. A three-dimensional model is decomposed into model surface portions, each of which has surface portion parameters. Reference data is received, which indicates real-world aerodynamic performance of a real-world object corresponding to the three-dimensional model. Simulated aerodynamic forces are calculated for the model surface portions based on their surface portion parameters. A simulated aerodynamic performance of the three-dimensional model is calculated based on combining the simulated aerodynamic forces of the model surface portions. Selected surface portion parameters are then adjusted based on comparing performance of the three-dimensional model to the reference data.

### BACKGROUND

Certain gaming software and other applications involve airplanes, automobiles or other virtual objects that interact with a virtual environment in a way that implicates aerodynamic performance. A variety of approaches have been used to model aerodynamic forces, for example to provide aircraft in a flight simulator with a realistic feel and behavior when being piloted by a user. Some methods involve an attempt to understand forces acting on individual portions of the aircraft. Other approaches involve taking data from real-world aircraft to guide how the virtual aircraft will perform in simulation.

### SUMMARY

A system and method are provided for configuring a three-dimensional model for aerodynamic simulation. The three-dimensional model is decomposed into model surface portions, each of which has surface portion parameters that influence simulated aerodynamic forces on the three-dimensional model. Reference data is received, which indicates real-world aerodynamic performance of a real-world object corresponding to the three-dimensional model. For each model surface portion, a simulated aerodynamic force is calculated based on the surface portion parameters of the model surface portion. A simulated aerodynamic performance of the three-dimensional model is calculated, based on combining the simulated aerodynamic forces of the model surface portions. Finally, surface portion parameters are adjusted for at least some of the model surface portions, based on comparing the simulated aerodynamic performance of the three-dimensional model to the reference data. Adjustments of the surface portion parameters may be performed in iterative cycles to bring simulated performance of the three-dimensional model to more closely align with real-world performance of the real-world object.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 depicts various three-dimensional models for which simulated aerodynamic performance may be configured.

FIG. 2 depicts a three-dimensional model and its decomposition into a plurality of model surface portions.

FIG. 3 depicts simulated translational and rotational aerodynamic forces for a model surface portion.

FIG. 4A depicts an exemplary method for configuring a three-dimensional model for aerodynamic simulation.

FIG. 4B depicts a matrix of states for a three-dimensional model and use of per-state normalization parameters to adjust surface portion parameters for the model surface portions of the three-dimensional model.

FIG. 5 depicts reference data for use in adjusting aerodynamic performance of a three-dimensional model.

FIG. 6 depicts an exemplary system for configuring a three-dimensional model for aerodynamic simulation.

FIG. 7 depicts an exemplary computing system for use in connection with systems and methods for configuring aerodynamic performance of a three-dimensional model

### DETAILED DESCRIPTION

The present description involves a mechanism for configuring a three-dimensional model for aerodynamic simulation. The mechanism enables one to cause and understand aerodynamic behavior in a virtual object (e.g., a plane or automobile), and to tune various parameters of the model to produce desired aerodynamic behavior in simulation. The examples discussed herein will primarily be directed to simulated aerodynamic performance of virtual aircraft, though it will be appreciated that the discussion applies equally to automobiles and other vehicles, stationary structures, and any other virtual object for which wind, air pressure, etc., are relevant considerations.

Understanding and modifying virtual aerodynamics has been approached via simulated wind tunnels, applying real-world data to analogous virtual aircraft, and considering portions of the aircraft in isolation to aid in approximating whole-object behavior. Some of these approaches can be quite responsive, in the sense that the simulated aircraft responds with sensitivity to pilot control inputs and virtual conditions (e.g., responsive to velocity, air pressure, wind gusts and other conditions). Some of these solutions, however, depart significantly from how aircraft behave in the real-world. In other cases, heightened realism can be achieved, but at the expense of a lively and exciting game feel for the user.

Accordingly, the present description provides for an improved method of configuring a three-dimensional model for simulated performance in a setting having aerodynamic considerations. The method involves breaking the model into a plurality of smaller constituent pieces. Specifically, the model is decomposed into a number of model surface portions. Each model surface portion corresponds to a part of the surface of the three-dimensional model which is affected by virtual air, wind, pressure, etc. Any number of surface portions can be used. Simulating a commercial aircraft, for example, might involve a few hundred model surface portions. Each model surface portion has surface portion parameters that influence the simulated aerodynamic forces it is subjected to (e.g., lift) for various simulated conditions (e.g., wind speed/direction, angle of attack, etc.).

Various methods may be used in connection with the individual model surface portions to model overall aerodynamic behavior of the three-dimensional model. However, in addition to internal modelling/computation, it will often be useful to employ “external data,” i.e., performance data from real-world objects. This external data may be used to correct errors arising from internal methods (i.e., model configurations achieved without referring to external reference data). Accordingly, in some cases, reference data will be received which indicates real-world aerodynamic performance of a real-world object that corresponds to the three-dimensional model—e.g., an actual aircraft. This may include aerodynamic performance under specified conditions. Using such reference data for adjusting model behavior will be described in detail below.

As discussed, for each of the model surface portions, simulated aerodynamic forces are calculated. These simulated forces are calculated based at least on the surface portion parameters of the model surface portion. For example, a given surface portion parameter might dictate a particular lift force under a certain set of conditions. Then, for the three-dimensional model as a whole, simulated aerodynamic performance is calculated based on combining the simulated aerodynamic forces for each of the model surface portions. Overall aerodynamic performance of the three-dimensional model may then be assessed, e.g., by applying virtual airflow in a simulated wind tunnel at different angles of attack (e.g., different angular positions relative to simulated wind movement/direction of travel).

In response to the above-described overall assessment of the three-dimensional model, individual surface portion parameters may be adjusted for at least some of the model surface portions. This adjustment is based on comparing the simulated aerodynamic performance of the three-dimensional model to external reference data related to performance of the real-world object. Such comparison essentially results in an error characterization that describes how the simulated performance of an aircraft deviates from actual performance of the real-world counterpart. For example, reference data may indicate that overall lift at the center of the aircraft is 10% too low for a particular angle of attack and wind speed. This insight can serve as a basis for adjustment. In many examples, adjustment may be iterative to correct for side effects and converge, over multiple iterative cycles, on a desired simulated performance for the three-dimensional model. In particular, as further described below, any given tuning of parameters made to achieve a correction is apt to produce other performance changes which depart from real-world values, and which therefore necessitate further iterative correction. The comparison and error characterization described above may be part of and implemented within a method using normalization parameters to adjust performance of the three-dimensional model, as described in detail below.

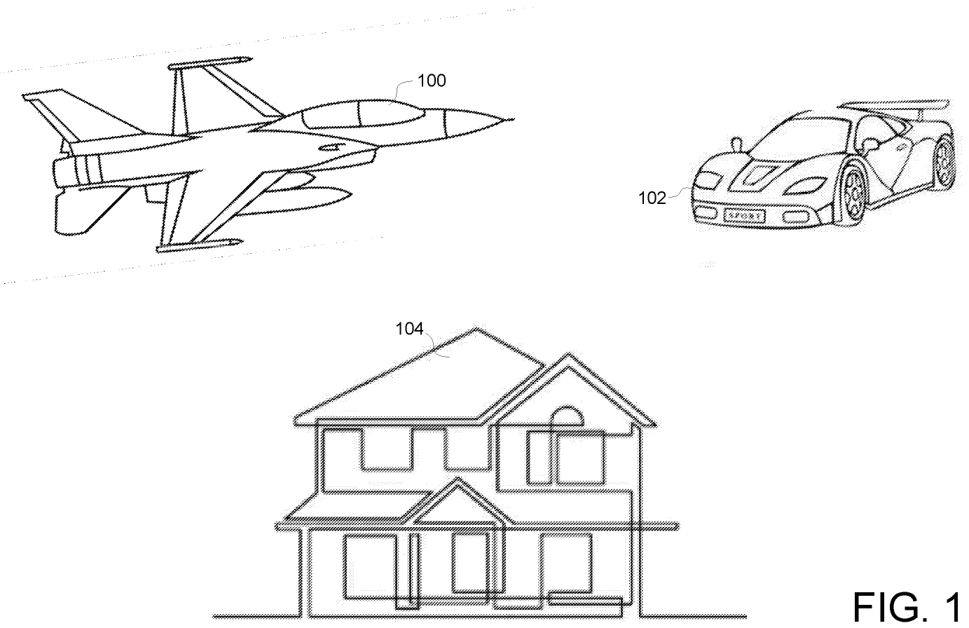

Referring now to FIG. 1, various three-dimensional models are depicted for which it may be desirable to configure for aerodynamic simulation—i.e., to cause the model to exhibit desired aerodynamic behavior. Specifically, three-dimensional models 100, 102 and 104 are respectively depicted for an aircraft, automobile and house or other stationary structure. In each case, it may be of interest to understand how, during simulation, wind and other aerodynamic conditions affect the model, e.g., how much drag and lift on an aircraft are produced by certain conditions? How should a model of a sports car be modified to increase spoiler downforce to a desired level? How should a virtual house be configured to perform realistically in a simulated storm?

For gaming and other applications, the models of FIG. 1 (100, 102, 104) will be often configured so that they are analogous to corresponding real-world objects. Flight simulators, for example, are often employed for entertainment, educational or training purposes. In many of these settings, it is desirable that the three-dimensional model of an aircraft correspond structurally to a real-world aircraft and behave, in aerodynamic simulation, in a way that closely mimics aerodynamic performance of the real-world aircraft. For example, when simulated wind speed/direction acts upon a virtual aircraft, the virtual aircraft should have a simulated aerodynamic performance (thrust/drag/lift/weight) that matches that of the corresponding real-world aircraft.

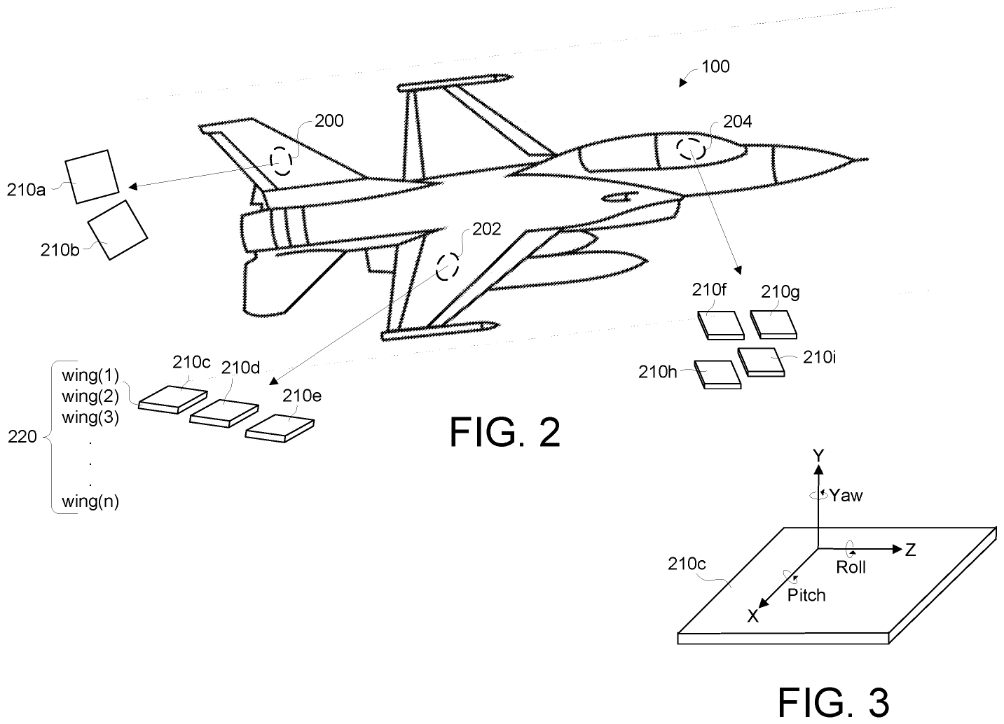

Referring now to FIG. 2, aspects of the present innovation will be described in which a three-dimensional computer model is segmented into a number of different portions, referred to herein as “model surface portions.” Each comprises a surface that is exposed to virtual wind, air pressure, etc. In typical examples, the model surface portions are discrete in the sense that they do not correspond in any recognizable way to specific discrete components of the three-dimensional model. In other words, the model surface portions are non-coextensive relative to discrete components of the three-dimensional model. For example, the model surface portions may be relatively small square or rectangular pieces that are not recognizable as any distinct portion of the three-dimensional model. For example, a wing of an aircraft may be broken up into perhaps 100 surface model portions, none of which would be recognizable as a wing. That said, solutions may be employed in which a single surface model portion is used for an entire wing, the fuselage, etc. Triangular and/or quadrilateral shapes will be desirable in many examples.

It will be further understood that model surface portions may be used in connection with moving parts. For example, on a real-world aircraft, various moving parts will affect aerodynamic performance, including movement of the rudder and wing flaps, and deployment and retraction of landing gear. Relative to landing gear, it will be further understood that in some states of the three-dimensional aircraft, the landing gear will not be exposed to the wind at all, in which case its model surface portions will not be relevant to some simulation calculations. Through use of a relatively large number of model surface portions, and surface portions of relatively small size, the present system and methods can capture performance subtleties, such as effects occurring from landing gear deployment, small movements of the flaps/rudder, turbulence, clouds, etc.

In particular, FIG. 2 depicts a three-dimensional model in the form of aircraft model 100. Aircraft model 100 has a rudder region 200 which is part of the aircraft rudder, a wing region 202 which is part of the right wing of the aircraft, and a canopy region 204 which is part of the canopy covering the cockpit. The regions are decomposed into model surface portions. In particular, two exemplary surface portions 210a and 210b are shown for rudder region 200; three exemplary surface portions 210c, 210d, and 210e are shown for wing region 202; and four exemplary surface portions 210f, 210g, 210h, and 210i are shown for canopy region 204.

It will be appreciated that each model surface portion 210 experiences virtual conditions in a particularized way—they are on different portions of the three-dimensional model 100, they are oriented differently relative to virtual wind, they experience different air pressures, etc. The overall aerodynamic performance of the three-dimensional model 100 is ultimately based on the individual aerodynamic properties/behavior of each model surface portion 210. In order to tune the contribution of each model surface portion to the overall aerodynamic performance of the three-dimensional model 100, each model surface portion 210 has associated surface portion parameters 220. Parameters 220 are shown for one of the wing surface portions, i.e., parameters wing(1), wing(2), etc. through wing(n) for surface portion 210c. It will be appreciated the parameters of various types may be associated with the other surface portions. The values of these parameters, along with other factors, enable calculation of one or more simulated aerodynamic forces for the respective model surface portion 210. For example, the calculation may yield values, for a specific model surface portion 210, for aerodynamic thrust, drag, weight, lift, etc.

At the conclusion of the above workflow, simulated aerodynamic forces are available for each of the model surface portions of the three-dimensional model. Example forces on model surface portion 210c are shown in FIG. 3, indicating translational forces in X, Y and Z directions, and rotational forces about X, Y, and Z axes (pitch, yaw, roll). The existence and magnitude of these forces are based on the parameters/coefficients associated with the model surface portion. Based on a combination of simulated aerodynamic forces (i.e., a combination of the forces for each decomposed model surface portion), simulated aerodynamic performance of the three-dimensional model may be calculated. In other words, performance for the model as a whole is derived based on the forces at each surface portion. Such simulated aerodynamic performance may include values of thrust, drag, lift and weight. Further, an accounting for such properties may be indicated for individual portions of the three-dimensional model, thereby yielding effects such as rotational forces and other simulated behavior accounting for different conditions at different parts of the three-dimensional model. For example, a virtual aircraft might experience different amounts of lift at respective left and right wings, thereby causing roll rotation (i.e., rotation about a z-axis extending along the direction of flight) and a banked turn.)

As indicated above, the tuning of the surface portion parameters for each model surface portion ultimately determines the aerodynamic behavior of the virtual model. In the context of a flight simulator, this tuning causes the virtual aircraft to behave in particular ways in response to virtual conditions and piloting inputs. In many cases, the resulting configuration will provide responsive and predictable performance that enables a user to effectively pilot the virtual aircraft However, in some cases, the aerodynamic tuning may be less than ideal. For example, many users of flight simulators are avid enthusiasts, and they desire that their virtual aircraft behave as closely as possible to the real-world counterpart. Accordingly, in many cases it will be desirable to modify aerodynamic behavior by adjusting the surface portion parameters to modify aerodynamic forces on one or more model surface portions, which in turn changes performance of the three-dimensional model as a whole.

One approach to such modification/adjustment is the use of reference data indicating real-world aerodynamic performance of a real-world object corresponding to the three-dimensional model. Such reference data in some cases may be provided by a manufacturers of the real-world object, e.g., wind tunnel data or other empirical data from an aircraft manufacturer for a specific aircraft being simulated. Such reference data may include performance data relating to lift, drag, etc. under a variety of conditions—e.g., wind speed/direction, temperature, barometric pressure, angle of attack, etc. Performance may also be specified in terms of normalization parameters that can be used to tune the surface portion parameters of model surface portions. In any event, the reference data is used to adjust the performance of the three-dimensional model. Specifically, one or more of the surface portion parameters of the three-dimensional model are adjusted based on comparing the simulated aerodynamic performance of the three-dimensional model to the reference data—i.e., a performance-to-performance comparison. Typically, the above adjustment is iterative, as it will often be the case that adjustment of surface portion parameters for one or more model surface portions will produce effects at other locations on the model which result in new errors to correct (i.e., deviations in performance of the model from how the real-world counterpart behaves).

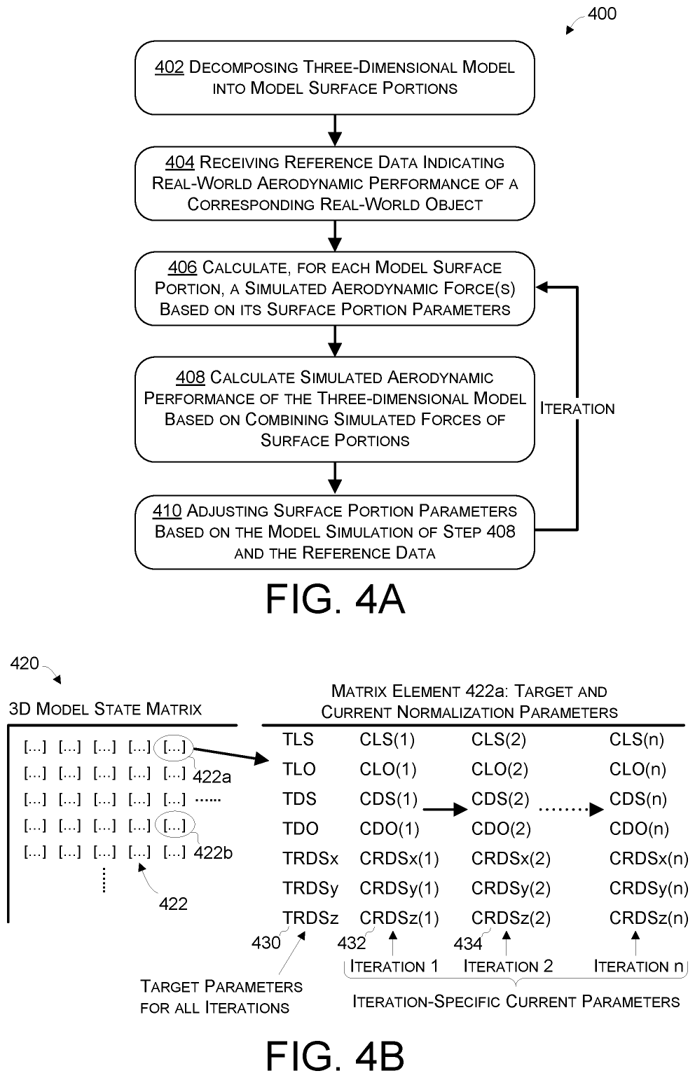

Referring now to FIG. 4, a method 400 of configuring a three-dimensional model for aerodynamic simulation is depicted. “Configuring,” as used herein, refers to manipulating the surface portion parameters of a three-dimensional model so that the model exhibits a desired simulated aerodynamic performance. As indicated above, virtual aircraft simulation is a useful setting for the method, though it is equally applicable to other virtual objects, such as structures, automobiles, etc.

At 402, the method entails decomposing a three-dimensional model, such as model 100, into model surface portions (e.g., portions 210), each of which has surface portion parameters (e.g., parameters 220 in FIG. 2) that influence simulated aerodynamic forces on the three-dimensional model. As indicated above, the model surface portions may be broken down in a variety of different ways and the surface portions may take different shapes sizes, etc. Typically, the model surface portions will not correspond in any recognizable way to distinct components of the three-dimensional object. For example, in the case of a house or other structure, a given model surface portion might not correspond to fully encompass a distinct component of the house such as a door, window, etc. Indeed, in some cases it may be desirable to have a relatively high number of model surface portions to provide a more granular control over the simulated aerodynamic forces on a three-dimensional model. For example, the wing of a large aircraft may be decomposed into 20, 50 or more model surface portions. On the other hand, a lesser number of model surface portions may reduce computational complexity.

The surface parameter approach may be implemented in a variety of different ways. In many examples, a parameter or parameters will be used to specify the size, shape and/or orientation/position of a model surface portion in 3D. For example, parameter wing(1) in FIG. 2 may specify the surface area of model surface portion 210c. A wide variety of parameters may be employed. Examples for parameters 220 include shape and size-related parameters, such as (1) 3D position of the surface portion; (2) 3D orientation of the surface portion; (3) front-facing and/or back facing area; and (4) local surface damage ratio. Other parameters may be directed to aerodynamic properties of the surface, such as (1) normal and tangential drag coefficients for front-facing and rear-facing aspects of the surface portion; (2) attached airflow coefficient; (3) detached airflow coefficient; (4) maximum angle of attack (stall alpha); and (5) local resistance to rotating air Cfmx, Cfmy, Cfmz. Other parameters may relate to airflow state, such as (1) current airflow attach ratio; (2) variation of current airflow attach ratio; (3) current air turbulence ratio; (4) local air speed in X, Y and Z directions; (5) local air rotation speed about X, Y and Z axes; (6) local air mach coefficient; and (7) local air density. Regarding the above factors, they may be implemented as coefficients or any other suitable way to as to influence the X/Y/Z pitch/yaw/roll force effects on surface portion 210c shown in FIG. 3. Further, these factors should be understood as non-limiting; a variety of other factors may be employed.

At 404, the example method includes receiving reference data indicating a real-world aerodynamic performance of a real-world object that corresponds to the three-dimensional model. In this regard, as noted above, many software applications involve three-dimensional models that strive to simulate or emulate actual corresponding objects in the real world. Aircraft in particular are popular objects for simulated modeling. In this case, a user/pilot typically desires that the three-dimensional object, when piloted or otherwise controlled, behave as closely as possible to the behavior of the corresponding real-world object. In a video game context, this involves developing the model and virtual environment to emulate the physics and real-world performance of the real-world object. As indicated above, even when sophisticated and computationally expensive techniques are applied, the emulated performance within the software application can depart in palpable ways from the performance of the real-world object. As will be discussed in more detail below, the reference data received at 404 may be employed to adjust model performance and bring it more in line with real-world behavior.

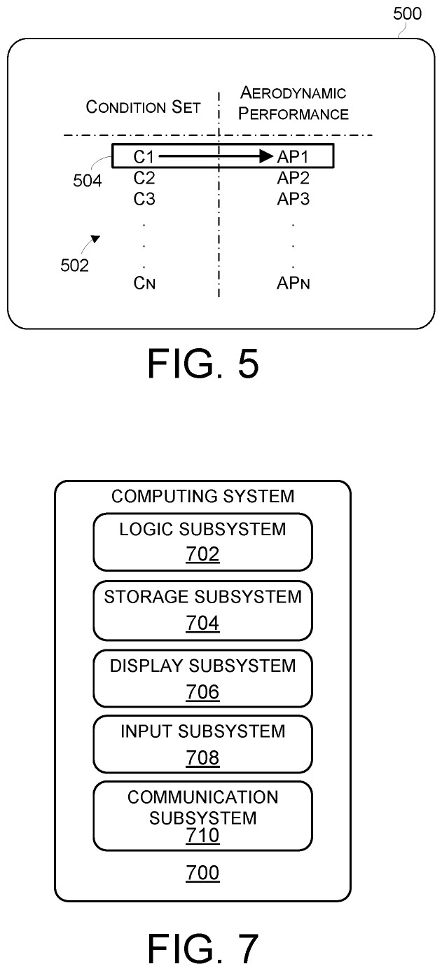

FIG. 5 depicts an example of reference data 500 for a real-world object. As indicated, in some cases it may be supplied by a vendor of the real-world object. For example, assuming an aircraft simulation of the famous Lockheed Model 14 Super Electra, the depicted reference data might be actual data provided by Lockheed Martin® (NOTE: this is intended to be exemplary only—reference data 500 does not in any way correspond to actual performance data of any Lockheed product or other real-world aircraft). The reference data may take any suitable form. In a depicted example, performance characteristics are provided for a variety of condition sets 502 shown in the leftmost column (i.e., condition sets C1, C2, C3 etc.). For example, as shown at 504, for condition set C1, the reference data yields real-world aerodynamic performance set AP1.

The condition sets C1, C2 etc. in some cases may be fairly simple, for example specifying only wind speed/direction and angle of attack. For such a condition set, the real-world aerodynamic performance may be a specification of lift at the center of the aircraft and/or other performance descriptors. More complicated condition sets might include altitude, barometric pressure, higher granularity specifications of aircraft position/orientation, flap/rudder positions, etc. In any event, the reference data 500 on some level enables an understanding of how simulated performance compares to that occurring in analogous real-world situations. More specifically, the reference data is usable to determine how simulated performance deviates from a goal (close mirroring of real-world performance), and how the model surface portion parameters 220 can be tuned to converge upon that goal. In some cases, reference data for a real-world object may be expressed in terms of normalization parameters that are based on and indicate the real-world performance of the real-world object, and which are used in connection with corresponding normalization parameters that are based on performance of the virtual model, in order to adjust surface portion parameters for the three-dimensional model and thereby adjust its aerodynamic performance.

Continuing with 406 of method 400, the workflow includes, for each of the model surface portions, calculating a simulated aerodynamic force (or forces) based on the surface portion parameters of the model surface portion (see forces of FIG. 3). As discussed above, the surface portion parameters may include parameters relating to the shape/orientation of the model surface portion, aerodynamic properties of the model surface portion (drag coefficients, resistance to rotating air), and airflow state (air translation/rotation speed, air density). Again, it will be appreciated that the model surface portion may be (and is in this example) an indistinct, decomposed surface portion which typically is smaller than a distinct component of the three-dimensional model that it is part of. In any event, the simulated aerodynamic force acting upon the model surface portion, as calculated using the surface portion parameters, may be resolved into X/Y/Z axis translational components and/or rotation about X/Y/Z axes (pitch/yaw/roll). The surface portion parameters may be of any number and type, and are tunable as further discussed below to influence the aerodynamic contribution of the model surface portion on the overall three-dimensional model.

At 408, the method further includes calculating simulated aerodynamic performance of the three-dimensional model based on combining the simulated aerodynamic forces that were calculated for the model surface portions. The combining operation may be performed in a variety of different ways, and may include sums, subtractions, averaging with or without weighting, etc. As used herein, “simulated aerodynamic performance” of the three-dimensional model may refer to a wide variety of descriptors of the three-dimensional model and its behaviors under certain conditions and in response to certain control inputs. For example, it may refer to thrust, drag, lift and weight; translational movements in X/Y/Z directions; pitch/yaw/roll rotation; behavior when faced with turbulence or other weather conditions; performance at different altitudes; performance characteristics and behavior when aircraft take off and land; etc. For aircraft and other three-dimensional models, it will be often desirable to calculate those properties with regard to a plurality of different angular positions of the three-dimensional model relative to simulated wind movement. This approach may be particular useful with aircraft, as real-world aircraft performance (i.e., reference data) is often specified with angle of attack as a variable.

Continuing with 408, the simulated performance of the three-dimensional model may be derived through a multi-stage workflow. First, the workflow may run over all of the model surface portions to calculate how the surfaces change the airflow received by the other model surface portions. The inputs in this regard may be the local air data, such as air speed and air density, and the output may be the local air data changed by the other surfaces. The model surface portions may then be processed independently to obtain a force (X/Y/Z) and moment (pitch/yaw/roll) per surface portion. These forces and moments may be summed and then applied to the overall integration of the airplane's translational speed and rotational speed. Local forces and moments may also be injected into a system that twists the airframe to simulated things like wing flex.

At 410, method 400 includes adjusting the surface portion parameters for at least some of the model surface portions, the adjustment being based on comparisons of the simulated aerodynamic performance of the three-dimensional model and reference data. As a general prospect, this adjustment is performed using the reference data in order to bring the simulated performance of the three-dimensional model more in line with the real-world performance of the aircraft or other object being simulated. That said, subsequent to an initial iteration, further adjustments may be performed in some cases without consulting external reference data.

In many cases, the parameter adjustments will produce side effects (often unforeseen) on performance of the three-dimensional model, with these effects in many cases being attributable to specific model surface portions. For example, in an aircraft simulation, reference data may show banked turn behavior in response to certain control inputs that differs from how the real aircraft would respond in real life. Adjustments to surface portion parameters at the wing flaps might then be carried out. Subsequent testing might then reveal that these flap adjustments cause undesirable yaw effects. These yaw effects might then point to the advisability of making adjustments to surface portion parameters on the rudder of the aircraft in order to stabilize lateral movement. These rudder corrections might in turn lead to other errors (e.g., departures from real-world performance), in turn leading to further adjustments of surface portion parameters, etc.

Accordingly, an iterative tuning may proceed as follows. First, as indicated with reference to 408 of FIG. 4, the simulated aerodynamic performance of the three-dimensional model is calculated and, as indicated above, this calculation involves some type of a combining of the simulated aerodynamic forces derived for each of the model surface portions. Next, this performance is assessed to gauge how and to what extent it aligns (or doesn't align) to that of the corresponding real-world object. This yields an error/discrepancy that may be characterized in a variety of different ways. As described below, the error/discrepancy maybe be characterized by, and corrected with, normalization parameters that reflect target and current aerodynamic performance of the three-dimensional model. Regardless of the specific error-determining methodology, the error is interpreted in a way that enables specific model surface portions to be adjusted to reduce the error. Reiterating the above aircraft example, an assessment that a banked turn under certain conditions deviates from how that turn would occur in the real-world can lead to a determination that model surface portions on the aircraft rudder need to be adjusted. More particularly, as discussed throughout this description, the adjustment may be implemented via modification of one or more surface parameters on one or more model surface portions of the three-dimensional model. This process would then continue until the type and level of error is reduced to an acceptable level. In other words, there would be further cycles of (1) configuring parameters to produce a simulated overall performance of the model; (2) comparing the simulated performance to reference data derived from real-world behavior/performance; (3) characterizing error, i.e., the nature and extent of the deviation from real-world behavior; (4) specifying what portions of the three-dimensional model need to be tuned—i.e., which model surface portions need to be adjusted, and how the associated parameters need to be modified; (5) making appropriate changes to arrive at a new simulation. One or more of these error-correcting iteration steps may be implicit in a technique involving normalization parameters associated with (1) the simulated performance of the model and (2) external reference data derived from real-world behavior.

More particularly, with reference to FIG. 4, the adjusting at 410 may be an initial adjustment. The method may then optionally include making a subsequent adjustment. Such subsequent adjustment may include identifying an error with the initial adjustment, for example an identification that the simulated aerodynamic performance calculated at 408 deviates from a desired performance. In some cases, such deviation is determined based on comparing the simulated aerodynamic performance calculated at 408 with reference data. In other examples, the error may be recognized internally, i.e., by simply noting that the three-dimensional model exhibits performance or behavior that is undesirable in some way (e.g., that a vehicle spoiler does not produce enough downforce to provide desired levels of traction). In any event, the optional subsequent adjustment may then include identifying one or more of the model surface portions attributable to the error and modifying their surface portion parameters. This subsequent adjustment process may be iterative, to include multiple cycles of subsequent adjustment to correct additional errors associated with prior adjustments.

The process of iteratively adjusting surface portion parameters may be understood in terms of states of a three-dimensional model. In the context of a three-dimensional aircraft model and its real-world counterpart, the method 400 may include, in connection with step 408 or otherwise, establishing a state descriptor for the model aircraft which descriptively captures all of the states of interest. In one example, this may be implemented as a matrix combining all possible sub-states of the aircraft, where example sub-states might include flap deployment angle; spoiler deployment angle; landing gear position; rudder angle; etc. Such a matrix is shown at 420 in FIG. 4B. The matrix includes a plurality of matrix elements 422, each of which describes a state of a three-dimensional model, such as airplane model 100. Again, in the context of an aircraft, a given state/element might specify a unique combination of sub-states for the aircraft such as particular flap angle, spoiler angle, etc. Performance typically will be calculated/simulated for each aircraft state, for example one performance might be for a first angle of attack, while another state might specify another angle of attack, among other possible sub-states/aspects. In general, the method of FIG. 4A may be applied to each of the states of the three-dimensional model.

For each element in the state matrix (i.e., a given combination of sub-states), seven normalization parameters may be employed. As discussed below, one set of these parameters may be for target performance (i.e., reference data indicating real-world aerodynamic performance of an aircraft, such as the reference data of 404 in FIG. 4A). Another set may be associated with the current performance of the three-dimensional model, i.e., the performance calculated at 408 in FIG. 4A for the model as a whole. These normalization parameters essentially are performance characterizations, respectively, for the real-world aircraft and the simulated aircraft, and they are compared iteratively to adjust performance of the virtual aircraft to converge its behavior toward that of the real-world aircraft. The normalization parameters are as follows:
1. Lift Slope (LS): This parameter relatives to adjusting the rate of change in lift, depending on the rate of change of angle of attack. This parameter is applied to the normal drag components, forward and rear facing, for model surface portions on the aircraft wings.
2. Lift Offset (LO): This parameter relates to adjusting the lift coefficients of the aircraft at an angle of attack of zero. This parameter results in a change of direction of the normal vector of surfaces of the aircraft.
3. Drag Slope (DS): This parameter relates to adjusting the rate of change in drag depending on the rate of change of the angle of attack. This parameter is applied to the EPiAr surface efficiency coefficients of the wings—i.e., attached and detached airflow coefficients.
4. Drag Offset (DO): This parameter relates to adjusting the drag coefficient of the aircraft at an angle of attack of zero. This parameter is applied to the tangent drag coefficients of surfaces that are vertical or lateral-facing and is applied to the normal drag coefficient of surfaces that are front facing.
5. Rotation resistance drag slope (RDSx, RDSy, RDSz): This parameter allows to adjust how much each surface will resist rotation (rotational drag based on rotational relative air speed). This parameter is applied to the local resistance to rotating air (Cfmx, Cfmy, Cfmz).

Referring again to 404, receiving the reference data may include evaluating a target normalization data set based on target aircraft performance data available for the real-world counterpart aircraft (i.e., “reference data” as used elsewhere herein). The data set for the normalization parameters may be expressed as Target values for Lift Slope, Lift Offset, Drag Slope, Drag Offset, and Rotation Resistance=TLS, TLO, TDS, TDO, TRDSx, TRDSy, TRDSz. These are indicated at the right side of FIG. 4B, which shows target and current normalization parameters for a state of the aircraft, as described by element 422a. The “current” normalization parameters are shown for multiple iterations.

Iterative correction may then proceed, where each iteration first includes, again referring to 408, evaluating the current performance of the virtual aircraft. As discussed above, this may include a combining operation that takes into account the simulated aerodynamic forces calculated at 406 in FIG. 4A for each of the model surface portions. Specifically, a given iteration may use current values of the surface portion parameters (e.g., parameters 220 in FIG. 2) to calculate forces at individual model surface portions and thus the performance for the model as a whole. This may yield current performance values for the normalization parameters as follows: Current values for Lift Slope, Lift Offset, Drag Slope, Drag Offset, Rotation Resistance=CLS, CLO, CDS, CDO, CRDSx, CRDSy, CRDSz.

Within the iteration, again referring to 410, changes are made to at least some of the current values of the surface portion parameters of the virtual aircraft. Using the target normalization parameters (i.e., reference data/performance of the actual aircraft) and the current normalization parameters for the particular iteration (the current performance of the virtual aircraft), the current values of the model surface portion parameters may be adjusted as follows via various comparisons of target normalization parameters and current normalization parameters:
Adjustment of surface portion parameters: normal Drag Facing coefficients are multiplied by TLS/CLS
Adjustment of surface portion parameters: change of direction of the normal vector is offset by (TLO−CLO)/TLS
Adjustment of surface portion parameters: EPiAr surface efficiency coefficients are multiplied by (TDS/CDS)/(TDO/CDO)
Adjustment of surface portion parameters: Tangent drag coefficients of surfaces that are vertical or lateral facing, and normal drag coefficients of surfaces that are front facing are multiplied by (TDO/CDO)
Adjustment of surface portion parameters: Local resistance to rotating air (Cfmx, Cfmy, Cfmz) is multiplied by TRDSx/CRDSx, TRDSy/CRDSy, TRDSz/CRDSz

In the first example iteration, referring to the right side of FIG. 4B, the target normalization parameters 430 are used together with the Iteration 1 current normalization parameters 432 to conduct the performance-to-performance comparison that adjusts the model surface portions. In the second iteration, target parameters 430 are used together with Iteration 2 current parameters 434 to adjust the surface portion parameters of the model surface portions. The depicted example processing continues to n iterations, where the surface portion parameters of the model are tuned at each iteration using the target normalization parameters with the current normalization parameters that were calculated for that iteration. In other words, the adjusted surface portion parameters at the end of a given iteration are fed back in as current surface portion parameters for the next iteration and are used to reassess the current adjusted performance of the virtual aircraft (i.e., as calculated at 408 in FIG. 4A). As seen in FIG. 4A, the iterative branching typically includes, after adjustment of the surface portion parameters at 410, a reassessment of the model performance (steps 406 and 408) so as to then derive the current normalization parameters for the next iteration.

Iterations may continue as appropriate, i.e., by repeating the evaluation of current performance at 410 and using the normalization parameters at 412 to adjust the surface portion parameters for the model surface portions and thereby tune simulation behavior of the overall model. In one example, errors are measured after each iteration, or after a certain number of iterations, and processing is terminated when error levels are satisfactory. In other examples, a set number of iterations are used based on assumptions that a certain amount of processing will provide the needed degree of adjustment.

From FIGS. 4A and 4B it will be appreciated that the described aerodynamic configuration may be carried out for a plurality of different states of a three-dimensional model aircraft and its real-world counterpart. The right side of FIG. 4B shows iterative performance comparisons (i.e., comparisons of current and target normalization parameters) in order to tune the model surface portion parameters for the model aircraft when it is in the state corresponding to the state of matrix element 422a (flaps in a particular angle, rudder at a particular angle/position, etc.). Matrix element 422b describes a different state (flaps at a different angle, perhaps the landing gear is down). For this element, a similar iterative process of current and target normalization parameters may be used to optimize the surface model portion parameters for when the model aircraft is in the state corresponding to element 422b. All of the other states in matrix 420 could similarly be tuned, such that for each defined state of the aircraft, the model surface portion parameters have been tuned and optimized to cause the 3D aircraft model to perform in a way that simulates real-world performance.

In some cases, the three-dimensional model aircraft will be between matrix states (e.g., flap position will be between two positions described at discrete portions of the matrix), in which case interpolation may be used to arrive at the correct model surface portion parameters. In other words, state-to-state interpolation may be used to derive model surface portion parameters.

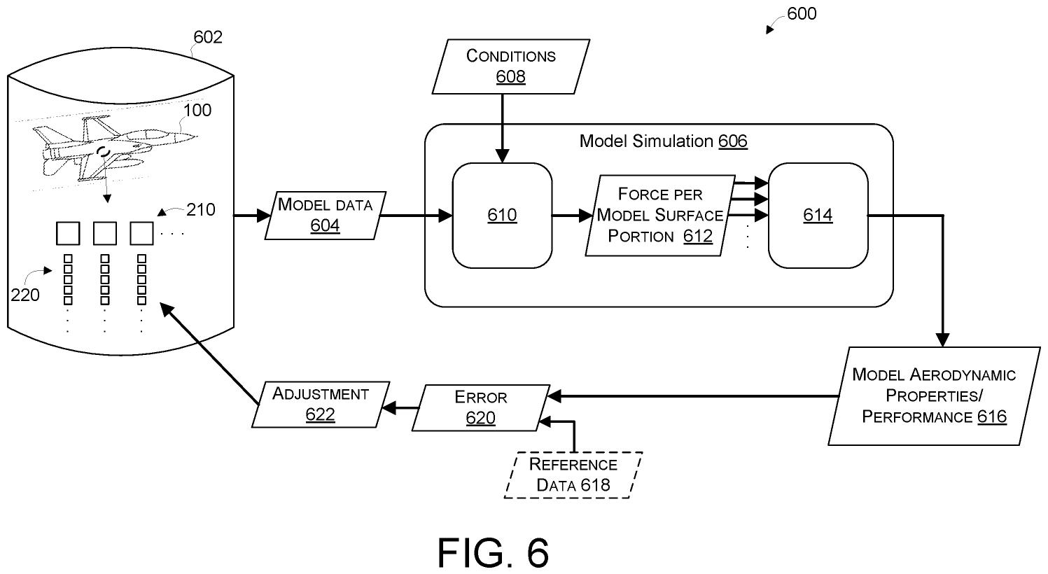

Many of the above concepts are brought together schematically in FIG. 6, including a description of software/hardware implementation in computing device components. The figure depicts a system 600 for configuring a three-dimensional model 100 for aerodynamic simulation. The system includes a storage subsystem 602 for storing information related to three-dimensional model 100. As in the above examples, the three-dimensional model may be decomposed into a number of model surface portions 210, each of which has associated surface portion parameters 220, such as the above-described shape/size, aerodynamic properties, and airflow state parameters. Model data information 604 is passed onto a model simulation module 606. Among other things, model data 604 includes the surface portion parameters 220. Conditions 608 are also fed into model simulation module 606. As discussed above, conditions 608 may include wind speed and direction; whether airflow is attached or detached; X/Y/Z and pitch/yaw/roll wind components; gusting and turbulence considerations; temperature; barometric pressure; altitude; proximity of trees, buildings or other topology features; etc. In some cases, conditions information 608 may be already built into the model surface portion parameters—e.g., in the form of one or more airflow state parameters such as air turbulence ratio, air rotation speed, and the like.

Within model simulation module 606, a sub-module 610 takes in model data 604 and conditions 608 (to the extent that they are not already reflected in the surface portion parameters), and processes those inputs to generate, at 612, a simulated aerodynamic force for each of the model surface portions 210 (e.g., in an X/Y/Z and pitch/yaw/roll force specification). The individual simulated forces are supplied to sub-module 614, which combines them via an appropriate methodology to generate model aerodynamic properties/performance 616. This essentially is the overall aerodynamic performance, in simulation, of three-dimensional model 100. In some examples, this overall performance is assessed via a simulated wind tunnel.

Iterative reconfiguration of the simulation is shown at 618, 620, and 622. Specifically, the performance at 616 may be assessed to determine the extent to which it deviates from a desired performance, for example a real-world performance. In many cases this error assessment will be performed in connection with reference data 618. The assessment may involve comparing performance 616 with the reference data 618. More particularly, with reference to 616 and 618, typical implementations involve virtual-to-real performance assessment via comparisons of target and current normalization parameters, as discussed above with reference to FIGS. 4A and 4B. Disparities between the normalization parameters entail an error 620 which produces adjustment 622 of the model surface portion parameters, as discussed above. These new model surface parameters in turn yield a new calculation of performance of the model at 610 and 614, to thereby produce an adjusted performance of the overall model, enabling further use of current and target normalization parameters to adjust the model surface portion parameters and achieve yet another performance of the overall model.

In certain settings, the systems and methods described herein can provide various advantages. By using a relatively large number of model surface portions, a high degree of granularity and sensitivity may be achieved. For example, the present methods can sensitively account for very dynamic situations in flight simulators, such as extreme rudder movement, volatile weather, asymmetrical stalls, and aerobatic maneuvers. The systems and methods can also intelligently account for when a virtual aircraft is near clouds, trees, buildings or other terrain features. As a general matter, since it is typical that all surfaces on an aircraft are accounted for with decomposed surface portions, regardless of what direction they face, a more complex handling of conditions is possible, including an accounting for lateral wind forces, turbulence, detached flow and the like. In particular, because each model surface portion has a different 3D position and orientation in the world, it is possible to sample the atmosphere separately for each surface and thereby get different local information for each surface. This allows the surfaces to have the actual air speed, air density, and air moment accurately, depending on their position in the virtual world. For example, as a result, if an aircraft has only one wing in a cloud, or in an updraft or in turbulence, it will only affect the corresponding surfaces and therefore create a very realistic simulation.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 7 schematically shows a non-limiting embodiment of a computing system 700 that can enact one or more of the methods and processes described above. Computing system 700 is shown in simplified form. Computing system 700 may take the form of one or more personal computers, server computers, tablet computers, home-entertainment computers, network computing devices, gaming devices, mobile computing devices, mobile communication devices (e.g., smart phone), and/or other computing devices.

Computing system 700 includes a logic subsystem 702 and a storage subsystem 704. Computing system 700 may optionally include a display subsystem 706, input subsystem 708, communication subsystem 710, and/or other components not shown in FIG. 7.

Logic subsystem 702 includes one or more physical devices configured to execute instructions, for example instructions configured to configure a three-dimensional object for aerodynamic simulation as described above. For example, the logic subsystem may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic subsystem may include one or more processors configured to execute software instructions. Additionally or alternatively, the logic subsystem may include one or more hardware or firmware logic subsystems configured to execute hardware or firmware instructions. Processors of the logic subsystem may be single-core or multi-core, and the instructions executed thereon may be configured for sequential, parallel, and/or distributed processing. Individual components of the logic subsystem optionally may be distributed among two or more separate devices, which may be remotely located and/or configured for coordinated processing. Aspects of the logic subsystem may be virtualized and executed by remotely accessible, networked computing devices configured in a cloud-computing configuration.

Storage subsystem 704 includes one or more physical devices configured to hold instructions executable by the logic subsystem to implement the methods and processes described herein. When such methods and processes are implemented, the state of storage subsystem 704 may be transformed—e.g., to hold different data.

Storage subsystem 704 may include removable and/or built-in devices. Storage subsystem 704 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 704 may include volatile, nonvolatile, dynamic, static, read/write, read-only, random-access, sequential-access, location-addressable, file-addressable, and/or content-addressable devices.

It will be appreciated that storage subsystem 704 includes one or more physical devices. However, aspects of the instructions described herein alternatively may be propagated by a communication medium (e.g., an electromagnetic signal, an optical signal, etc.) that is not held by a physical device for a finite duration.

Aspects of logic subsystem 702 and storage subsystem 704 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 700 implemented to perform a particular function. In some cases, a module, program, or engine may be instantiated via logic subsystem 702 executing instructions held by storage subsystem 704. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

It will be appreciated that a “service”, as used herein, is an application program executable across multiple user sessions. A service may be available to one or more system components, programs, and/or other services. In some implementations, a service may run on one or more server-computing devices.

When included, display subsystem 706 may be used to present a visual representation of data held by storage subsystem 704. This visual representation may take the form of a graphical user interface (GUI). As the herein described methods and processes change the data held by the storage subsystem, and thus transform the state of the storage subsystem, the state of display subsystem 706 may likewise be transformed to visually represent changes in the underlying data. Display subsystem 706 may include one or more display devices utilizing virtually any type of technology. Such display devices may be combined with logic subsystem 702 and/or storage subsystem 704 in a shared enclosure, or such display devices may be peripheral display devices.

When included, input subsystem 708 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for subsystem vision and/or gesture recognition; a head tracker, eye tracker, accelerometer, and/or gyroscope for motion detection and/or intent recognition; as well as electric-field sensing componentry for assessing brain activity.

When included, communication subsystem 710 may be configured to communicatively couple computing system 700 with one or more other computing devices. Communication subsystem 710 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 700 to send and/or receive messages to and/or from other devices via a network such as the Internet.

According to a first example of the disclosure, a method is provided for configuring a three-dimensional model for aerodynamic simulation. The method includes (1) decomposing the three-dimensional model into model surface portions, each model surface portion having surface portion parameters that influence simulated aerodynamic forces on the three-dimensional model; (2) receiving reference data indicating real-world aerodynamic performance of a real-world object corresponding to the three-dimensional model; (3) calculating, for each of the model surface portions, a simulated aerodynamic force based on the surface portion parameters of the model surface portion; (4) calculating simulated aerodynamic performance of the three-dimensional model, based on combining the simulated aerodynamic forces of the model surface portions; and (5) adjusting the surface portion parameters for at least some of the model surface portions, based on comparing the simulated aerodynamic performance of the three-dimensional model to the reference data.

In the first example, the adjustment may be an initial iteration of adjustment among a plurality of iterations, where each iteration includes (1) using current values of the surface portion parameters to calculate simulated aerodynamic performance of the three-dimensional model for a current iteration; and (2) adjusting one or more of the current values of the surface portion parameters based on based on comparing the simulated aerodynamic performance of the three-dimensional model to the reference data, where such adjustment yields current values of the surface portion parameters to be used in a successive iteration of the plurality of iterations. The first example may further include establishing a plurality of different states of the three-dimensional model, and where the decomposing and adjusting of surface portion parameters is performed for each of the different states. Interpolation may be made between different states of the plurality of different states to derive a surface portion parameter for a model surface portion.

In the first example, the model surface portions may be one or both of triangles and quadrilaterals. The three-dimensional model may be an aircraft model and the real-world object may be a real-world aircraft. The surface portion parameters may include a specification of one or more of a shape, position and orientation of the model surface portion. The surface portion parameters may include a specification of one or more aerodynamic properties of the model surface portion. The surface portion parameters may include a specification of an airflow state in relation to the model surface portion. The simulated aerodynamic force may include specification of translational force components along X, Y and Z axes, and/or rotational force components about X, Y and Z axes.

A system for configuring a three-dimensional model for aerodynamic simulation is provided according to a second example of the disclosure. The system includes a logic subsystem and a storage subsystem configured to store the three-dimensional model. The storage subsystem is further configured to store instructions that are executable by the logic subsystem to (1) decompose the three-dimensional model into model surface portions, each model surface portion having surface portion parameters that influence simulated aerodynamic forces on the three-dimensional model; (2) receive reference data indicating real-world aerodynamic performance of a real-world object corresponding to the three-dimensional model; (3) calculate, for each of the model surface portions, a simulated aerodynamic force based on the surface portion parameters of the model surface portion; (4) calculate simulated aerodynamic performance of the three-dimensional model, based on combining the simulated aerodynamic forces of the model surface portions; and (5) adjust the surface portion parameters for at least some of the model surface portions, based on comparing the simulated aerodynamic performance of the three-dimensional model to the reference data.

In this second example, the adjustment may be an initial iteration of adjustment among a plurality of iterations, the instructions being further configured so that each iteration includes: (1) using current values of the surface portion parameters to calculate simulated aerodynamic performance of the three-dimensional model for a current iteration; and (2) adjusting one or more of the current values of the surface portion parameters based on based on comparing the simulated aerodynamic performance of the three-dimensional model to the reference data, where such adjustment yields current values of the surface portion parameters to be used in a successive iteration of the plurality of iterations.

The instructions of the second example may be further configured to establish a plurality of different states of the three-dimensional model, and where the decomposing and adjusting of surface portion parameters is performed for each of the different states.

In the second example, (1) the three-dimensional model may be an aircraft model and the real-world object may be a real-world aircraft; (2) the surface portion parameters may include a specification of one or more of a shape, position and orientation of the model surface portion; (3) and the simulated aerodynamic force may include specification of translational force components along X, Y and Z axes, and/or rotational force components about X, Y and Z axes.

According to a third example, a system is provided for configuring a three-dimensional aircraft model for aerodynamic simulation. The system includes logic subsystem and a storage subsystem configured to store the three-dimensional aircraft model, the storage subsystem further configured to store instructions that are executable by the logic subsystem to, for each of a plurality of different states of the three-dimensional aircraft model: (1) decompose the three-dimensional aircraft model into model surface portions, each model surface portion having surface portion parameters that influence simulated aerodynamic forces on the three-dimensional aircraft model; (2) receive reference data indicating real-world aerodynamic performance of a real-world aircraft corresponding to the three-dimensional aircraft model; (3) calculate, for each of the model surface portions, a simulated aerodynamic force based on the surface portion parameters of the model surface portion, such simulated aerodynamic force including one or any combination of translation force components along X, Y and Z axes and rotational force components about X, Y and Z axes; (4) calculate simulated aerodynamic performance of the three-dimensional aircraft model, based on combining the simulated aerodynamic forces of the model surface portions; and (5) iteratively adjust the surface portion parameters for at least some of the model surface portions, based on comparing the simulated aerodynamic performance of the three-dimensional aircraft model to the reference data.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of configuring a three-dimensional model for aerodynamic simulation, including:
decomposing the three-dimensional model into model surface portions, each model surface portion having surface portion parameters that influence simulated aerodynamic forces on the three-dimensional model;
receiving reference data indicating real-world aerodynamic performance of a real-world object corresponding to the three-dimensional model;
calculating, for each of the model surface portions, a simulated aerodynamic force based on the surface portion parameters of the model surface portion;
calculating simulated aerodynamic performance of the three-dimensional model, based on combining the simulated aerodynamic forces of the model surface portions; and
adjusting the surface portion parameters for at least some of the model surface portions, based on comparing the simulated aerodynamic performance of the three-dimensional model to the reference data.

2. The method of claim 1, wherein the adjustment is an initial iteration of adjustment among a plurality of iterations, where each iteration includes:
using current values of the surface portion parameters to calculate simulated aerodynamic performance of the three-dimensional model for a current iteration; and
adjusting one or more of the current values of the surface portion parameters based on based on comparing the simulated aerodynamic performance of the three-dimensional model to the reference data, where such adjustment yields current values of the surface portion parameters to be used in a successive iteration of the plurality of iterations.

3. The method of claim 1, further comprising establishing a plurality of different states of the three-dimensional model, and where the decomposing and adjusting of surface portion parameters is performed for each of the different states.

4. The method of claim 3, further comprising interpolating between different states of the plurality of different states to derive a surface portion parameter for a model surface portion.

5. The method of claim 1, wherein the model surface portions are non-coextensive relative to discrete surface components of the real-world object.

6. The method of claim 1, wherein the model surface portions are one or both of triangles and quadrilaterals.

7. The method of claim 1, wherein the three-dimensional model is an aircraft model and the real-world object is a real-world aircraft.

8. The method of claim 1, wherein the surface portion parameters include a specification of one or more of a shape, position and orientation of the model surface portion.

9. The method of claim 1, wherein the surface portion parameters include a specification of one or more aerodynamic properties of the model surface portion.

10. The method of claim 1, wherein the surface portion parameters include a specification of an airflow state in relation to the model surface portion.

11. The method of claim 1, wherein the simulated aerodynamic force includes specification of translational force components along X, Y and Z axes.

12. The method of claim 1, where the simulated aerodynamic force includes specification of rotational force components about X, Y and Z axes.

13. A system for configuring a three-dimensional model for aerodynamic simulation, comprising:
a logic subsystem; and
a storage subsystem configured to store the three-dimensional model, the storage subsystem further configured to store instructions that are executable by the logic subsystem to:
decompose the three-dimensional model into model surface portions, each model surface portion having surface portion parameters that influence simulated aerodynamic forces on the three-dimensional model;
receive reference data indicating real-world aerodynamic performance of a real-world object corresponding to the three-dimensional model;
calculate, for each of the model surface portions, a simulated aerodynamic force based on the surface portion parameters of the model surface portion;
calculate simulated aerodynamic performance of the three-dimensional model, based on combining the simulated aerodynamic forces of the model surface portions; and
adjust the surface portion parameters for at least some of the model surface portions, based on comparing the simulated aerodynamic performance of the three-dimensional model to the reference data.

14. The system of claim 13, wherein the adjustment is an initial iteration of adjustment among a plurality of iterations, the instructions being further configured so that each iteration includes:
using current values of the surface portion parameters to calculate simulated aerodynamic performance of the three-dimensional model for a current iteration; and
adjusting one or more of the current values of the surface portion parameters based on based on comparing the simulated aerodynamic performance of the three-dimensional model to the reference data, where such adjustment yields current values of the surface portion parameters to be used in a successive iteration of the plurality of iterations.

15. The system of claim 13, the instructions being further configured to establish a plurality of different states of the three-dimensional model, and where the decomposing and adjusting of surface portion parameters is performed for each of the different states.

16. The system of claim 13, wherein the three-dimensional model is an aircraft model and the real-world object is a real-world aircraft.

17. The system of claim 13, wherein the surface portion parameters include a specification of one or more of a shape, position and orientation of the model surface portion.

18. The system of claim 13, wherein the simulated aerodynamic force includes specification of translational force components along X, Y and Z axes.

19. The system of claim 13, where the simulated aerodynamic force includes specification of rotational force components about X, Y and Z axes.

20. A system for configuring a three-dimensional aircraft model for aerodynamic simulation, comprising:
a logic subsystem; and
a storage subsystem configured to store the three-dimensional aircraft model, the storage subsystem further configured to store instructions that are executable by the logic subsystem to, for each of a plurality of different states of the three-dimensional aircraft model:
decompose the three-dimensional aircraft model into model surface portions, each model surface portion having surface portion parameters that influence simulated aerodynamic forces on the three-dimensional aircraft model;
receive reference data indicating real-world aerodynamic performance of a real-world aircraft corresponding to the three-dimensional aircraft model;
calculate, for each of the model surface portions, a simulated aerodynamic force based on the surface portion parameters of the model surface portion, such simulated aerodynamic force including one or any combination of translation force components along X, Y and Z axes and rotational force components about X, Y and Z axes;
calculate simulated aerodynamic performance of the three-dimensional aircraft model, based on combining the simulated aerodynamic forces of the model surface portions; and
iteratively adjust the surface portion parameters for at least some of the model surface portions, based on comparing the simulated aerodynamic performance of the three-dimensional aircraft model to the reference data.
